(19) United States
(12) Patent Application Publication
(10) Pub. No.: US 2015/0022231 A1
(43) Pub. Date: Jan. 22, 2015

(54) Test Apparatus with Sector Conveyance Device

(71) Applicant: CHROMA ATE INC., Taoyuan County (TW)

(72) Inventors: Yi-Chiao Lee, Taoyuan County (TW); Xin-Yi Wu, Taoyuan County (TW)

(73) Assignee: CHROMA ATE INC., Taoyuan County (TW)

(21) Appl. No.: 14/333,282

(22) Filed: Jul. 16, 2014

(30) Foreign Application Priority Data
Jul. 18, 2013 (TW) 102125805

(51) Int. Cl. G01R 31/28

(52) U.S. Cl. CPC G01R 31/2893
USPC 324/757.01

(57) ABSTRACT

A test apparatus includes a sector conveyance device provided with a plurality of soaking buffers, the soaking buffers being used to carry electronic components, the sector conveyance device being mounted pivotably by a pivot and moved between a test location and a transferring location; a transferring device arranged in correspondence to the transferring location, used to transfer a plurality of electronic components into or out of the sector conveyance device; and a test device arranged in correspondence to the test location for testing electronic components, the electronic components being transferred into the sector conveyance device after test.

### BACKGROUND OF THE INVENITON

1. Field of the Invention

The present invention relates to a test apparatus, particularly to a test apparatus with a sector conveyance device.

2. Description of the Related Art

With the wide application of electrical products, electronic components thereof are usually requested to work in severe environments. Vendors have to ensure the endurance of the electronic components, such as Integrated circuits (ICs), with respect to various temperatures in order to prevent the electronic components from failure in critical situations. Severely, the electronic components on cars may malfunction in a snow weather or on a highway of desert, such that drivers might suffer from life danger. In the application of electronic components to the military equipment or weather prediction, serious consequences and a large amount of damages might occur due to malfunction of some of the electronic components. Thus, in order to guarantee stability of electronic components, tests in different temperatures are necessary to simulate different application environments, and test the operative performance of the electronic components under these conditions.

A conventional test apparatus is shown in FIG. 1, wherein a thermal insulation chamber 90 is divided into an area of a thermally conditioning device 92 and an area of a test device 91. With respect to an actual operation, for example, the test in a low temperature environment, the thermally conditioning device 92 cools down the electronic components to be tested from the outside ambient temperature slowly, while a predetermined operating temperature is held in the thermal insulation chamber 90. After the electronic components to be tested are cooled to the predetermined operating temperature, they are transferred to the test device 91 and tested in the predetermined operating temperature. Alternatively, the electronic components to be tested are heated by the thermally conditioning device 92 to perform, for example, an ageing test.

There are following problems derived from the existing test apparatus. The volume of the apparatus cannot be reduced, such that the volume of the thermal insulation chamber is giant accordingly because each of the thermally conditioning device and the test device needs an independent space. Subsequently, the temperature control and humidity control inside the thermal insulation chamber mean a large amount of energy consumption, such that the test cost increases accordingly. Furthermore, if the electronic components under a low temperature test are revealed to normal temperature air with a certain humidity, moisture in the normal temperature air will be condensed rapidly onto the surfaces of the electronic components due to the contact with the low temperature electronic components, and even result in frosting. In order to prevent metal wires from rusting or avoid short circuit between contacts in the electronic components caused by the rapidly condensed moisture, the thermally conditioning device used before testing the electronic components and the temperature return device used after testing the electronic components have to be separated in the existing apparatus.

From above, it is recognized that the structure space of the conventional test apparatus cannot be reduced, and the space issue and high cost of the apparatus cannot be improved. Unnecessary space waste can be economized significantly and the volume of apparatus can be reduced effectively if the test device and thermally conditioning device can share the same space and if the thermally conditioning device can perform the first half process, in which the temperature is varied from the ambient temperature to the target temperature, and the second half process, in which the temperature returns from the target temperature, simultaneously. The energy for maintaining the target temperature and the energy loss can also be reduced significantly to reduce the test cost.

### SUMMARY OF THE INVENTION

One object of the present invention is to provide a test apparatus in which various devices share the same space in order to save volume.

Another object of the present invention is to provide a test apparatus with low energy consumption in order for saving the test cost.

A further object of the present invention is to provide a test apparatus operating with a sector conveyance device and a test device in accordance through pivoted swing of the sector conveyance device.

A yet another object of the present invention is to provide a test apparatus which includes a simplified structure and in which the space for use is reduced.

A test apparatus with sector conveyance device includes: a sector conveyance device, mounted pivotably by a pivot and formed with a plurality of soaking buffers, the soaking buffers being used to carry a plurality of electronic components, the sector conveyance device being pivoted to a test location or transferring location via the pivot; a transferring device arranged in correspondence to the transferring location, used to transfer each of the electronic components into or out of the sector conveyance device; a test device arranged in correspondence to the test location, used to test, in the test location, one electronic component, among the electronic components, picked up from the sector conveyance device, and place the tested one electronic component in the sector conveyance device after testing the one electronic component; wherein, after the one electronic component is tested, during a period in which the test device tests a next electronic component to be tested, the sector conveyance device is pivoted away from the test location to the transferring location so that the tested one electronic component is transferred out of the sector conveyance device by the transferring device and a new electronic component is transferred into the sector conveyance device by the transferring location.

The present invention attempts to provide a test apparatus sector conveyance device, wherein the sector conveyance device is mounted pivotably by a pivot, such that a test device, a sector conveyance device and a transferring device may share the same operating space. With the cooperation of the test device, the sector conveyance device and the transferring device, during a period in which the test device performs a test operation, the sector conveyance device, in conjunction with the transferring device, transfers a tested electronic component out of the sector conveyance device, and feeds a new electronic component into the sector conveyance device. With such a structure, the occupied space is reduced significantly on one hand, and the energy loss in operating process may be reduced significantly on the other hand, together with reducing the cost necessary in testing process.

### BRIEF DESCRIPTION OF THE DRAWINGS

FIG. 1 is a top view of a conventional test apparatus;

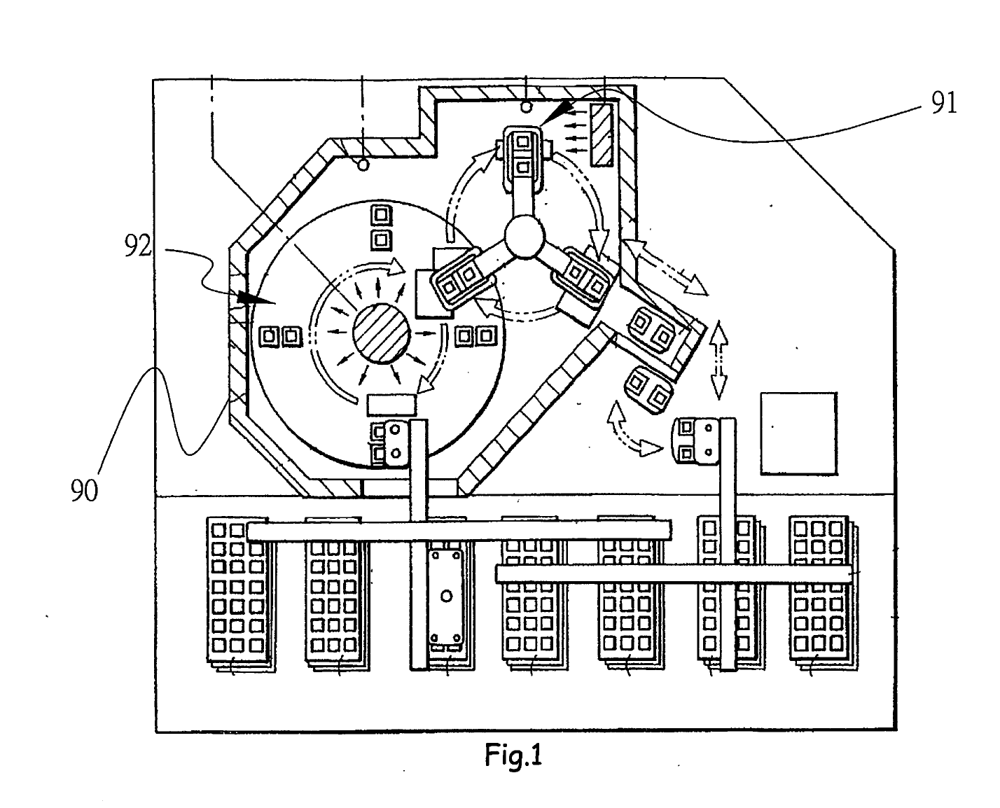

FIG. 2 is a perspective view of a first embodiment of the present invention, which shows a condition in which a sector conveyance device operating between a transferring location and a test location; and a situation in which a test device is pushed downwards at the test location after the sector conveyance device is turned away;

FIG. 3 is a side view of the sector conveyance device of the first embodiment of the present invention, which shows the structural relationship between soaking buffers and heat exchanger modules;

FIG. 4 is a perspective view of the first embodiment of the present invention, which shows relative locations of various devices;

FIG. 5 is a partial lateral view of the first embodiment of the present invention, which shows the operation of the robot arm;

FIG. 6 is a top view of the first embodiment of the invention, which shows the operation of the sector conveyance device;

FIG. 7 is a perspective view of a second embodiment of the present invention, which shows a test apparatus with a shuttle;

FIG. 8 is a side view of the sector conveyance device of the second embodiment of the present invention, which shows the operation of a standing buffer.

### DESCRIPTION OF THE PREFERRED EMBODIMENTS

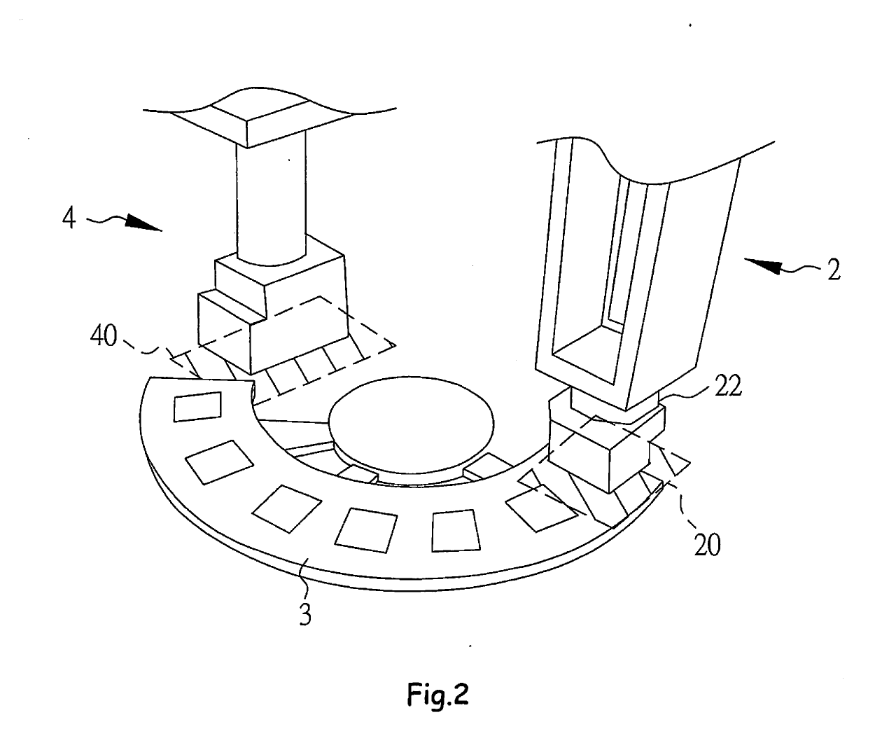

FIG. 2 shows a test apparatus of the present invention. The apparatus includes a transferring device 2 arranged in correspondence to a transferring location 20; a test device 4 arranged in correspondence to a test location 40; and a sector conveyance device 3 pivoted between the transferring location 20 and the test location 40. At first, the transferring device 2 utilizes a transferring arm 22 to transfer electronic components to be tested onto the sector conveyance device 3 on standby in the transferring location 20. For simplicity, in the following description, the electronic components are exemplified as integrated circuits (ICs).

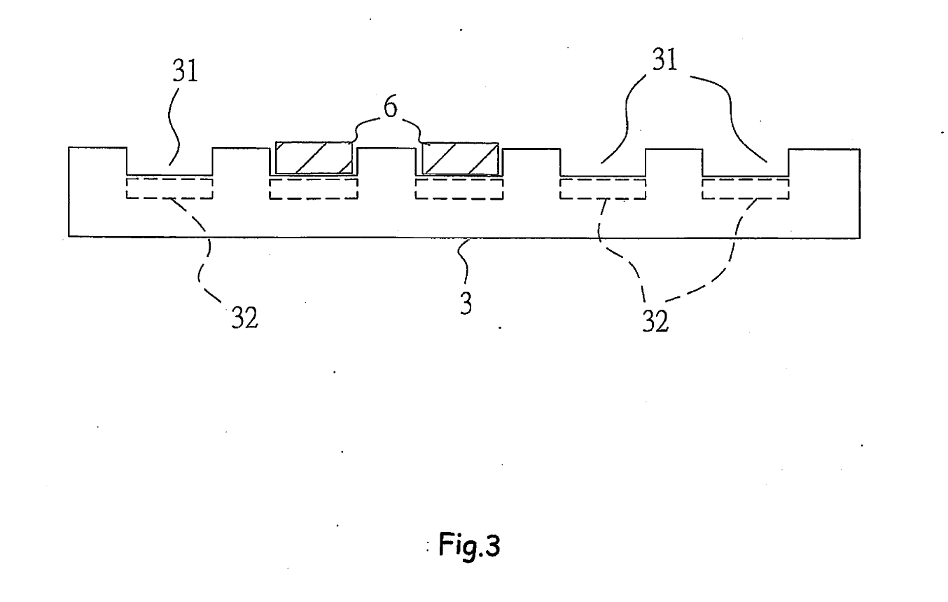

As shown in FIG. 3, a plurality of soaking buffers 31 in form of containing grooves are formed on the sector conveyance device 3. Each soaking buffer 31 is provided with a heat exchanger module 32 at the bottom, and may receive an IC 6 to be tested. The IC 6 is brought in contact with the heat exchanger module 32 and thermally conditioned (for example, heated or cooled) by the heat exchanged module 32. Of course, those skilled in the art may understand easily that ICs to be tested may also be components such as LEDs. In addition, the above heat exchanger modules may also be replaced with independent heating coils or cooling chips without impeding the implementation of the present invention.

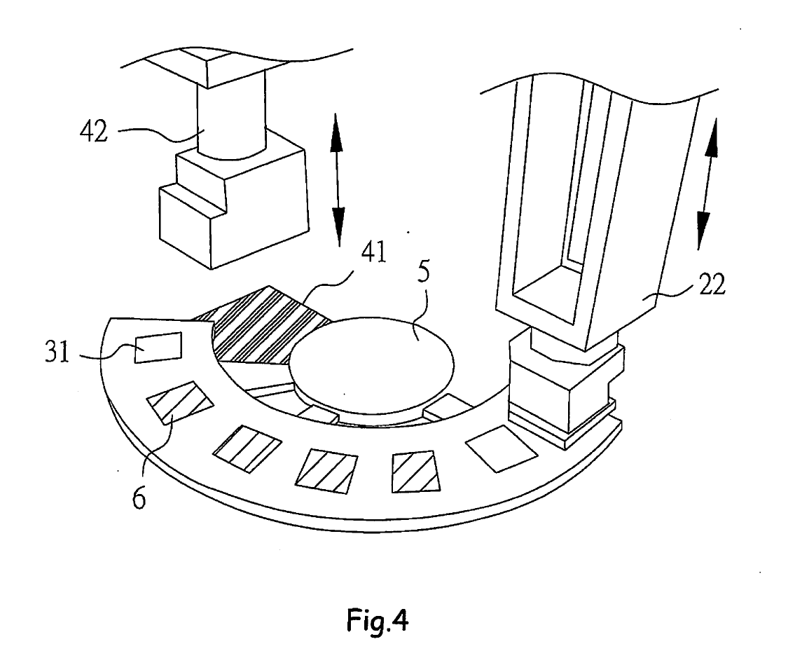

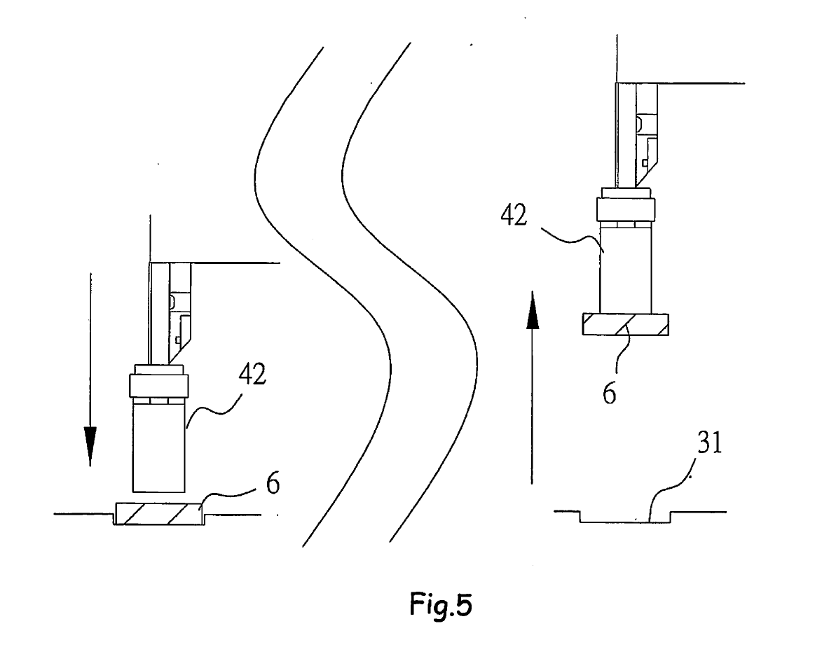

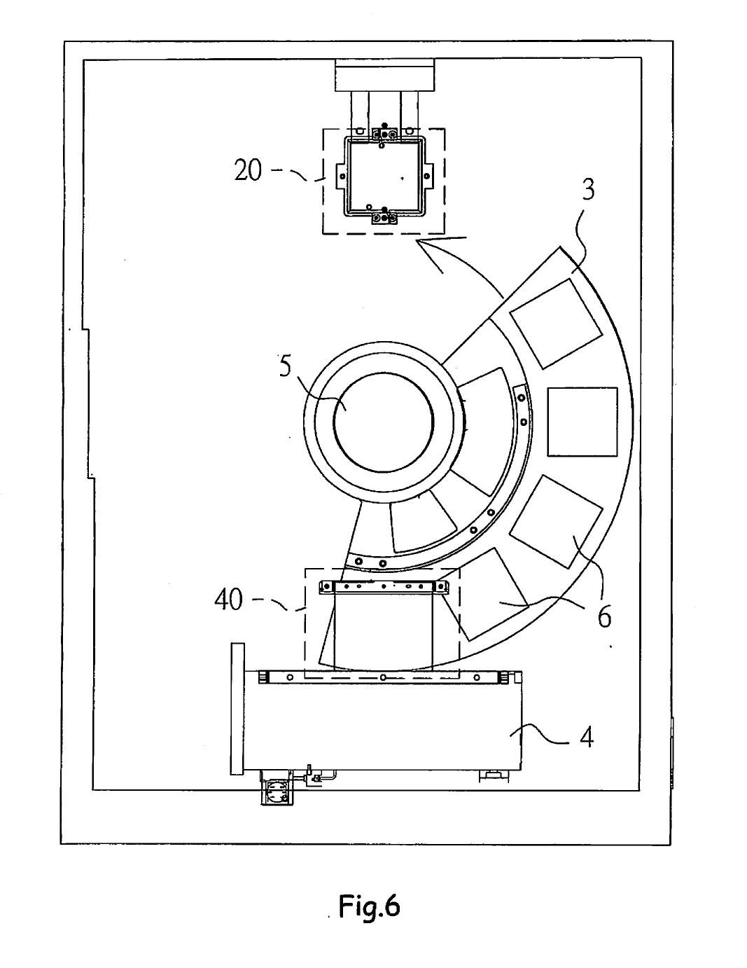

The description of the low temperature test will be made by referring to FIGS. 4 to 6. After the transferring arm 22 transfers the IC 6 to be tested into the sector conveyance device 3, the sector conveyance device 3 will be pivoted between the transferring location 20 and the test location 40 by a pivot 5 to receive another IC 6 to be tested or the IC which has been tested. While the sector conveyance device is pivoted, the IC 6 to be tested just placed is still held in the same soaking buffer 31 so as to guarantee sufficient cooling time for that IC 6. A determined cooling time is calculated and set in such a way that the temperature inside the IC 6 is made close to a predetermined target temperature and that a real temperature environment in which the IC operates is approximated.

If the IC 6 to be tested is sufficiently cooled, then the IC 6 is subjected to the test in turn. The other ICs 6 just transferred into the sector conveyance device 3 is cooled continuously at the same time, in order to ensure that the interior of each IC 6 under test is also cooled to an appropriate operating temperature. A robot arm 42 of the test device 4 has placed the IC 6 that has been tested on one of the soaking buffers 31. The sector conveyance device 3 is pivoted by the pivot 5 again so as to turn the soaking buffer 31, on which the IC 6 to be tested that has been cooled sufficiently is placed, to the test location 40. The robot arm 42 of the test device 4 picks up the IC 6 to be tested away from the soaking buffer 31 through a suction of, for example, a vacuum suction nozzle.

At this moment, the sector conveyance device 3 is pivoted by the pivot 5 again, and the soaking buffer 31, on which the IC 6 that has been tested with sufficient temperature return is arranged, is pivoted to the transferring location 20. The shape of the sector conveyance device 3 is designed as sector for the purpose that the test location 40 will be emptied as the sector conveyance device 3 turns away from the test location 40 toward the transferring location 20 after the robot arm 42 picks up the IC 6 to be tested. As such, the robot arm 42 of the test device 4 may push downwards the picked IC 6 to be tested to the test base 41 so that the IC 6 to be tested is fitted tightly with each contact of the test device 4, in order to prevent the existence of any gap, which affects electrical connection and results in misjudgment of product quality.

The sector conveyance device 3 according to the present invention is so designed that not only a space is left for elevation of the robot arm 42, but also a distance is kept between the sector conveyance device 3 and the test location 40 where the robot arm 42 is located after accomplishment of feeding and the sector conveyance device being pivoted away. Thereby, the sector conveyance device 3 according to the present invention may perform clockwise pivot or counter clockwise pivot without contact with the robot arm 42 that is pushed downwards. Therefore, all of soaking buffers 31 may be used with adaptation to different situations when the IC 6 to be tested is in test, such that utilization flexibility is increased.

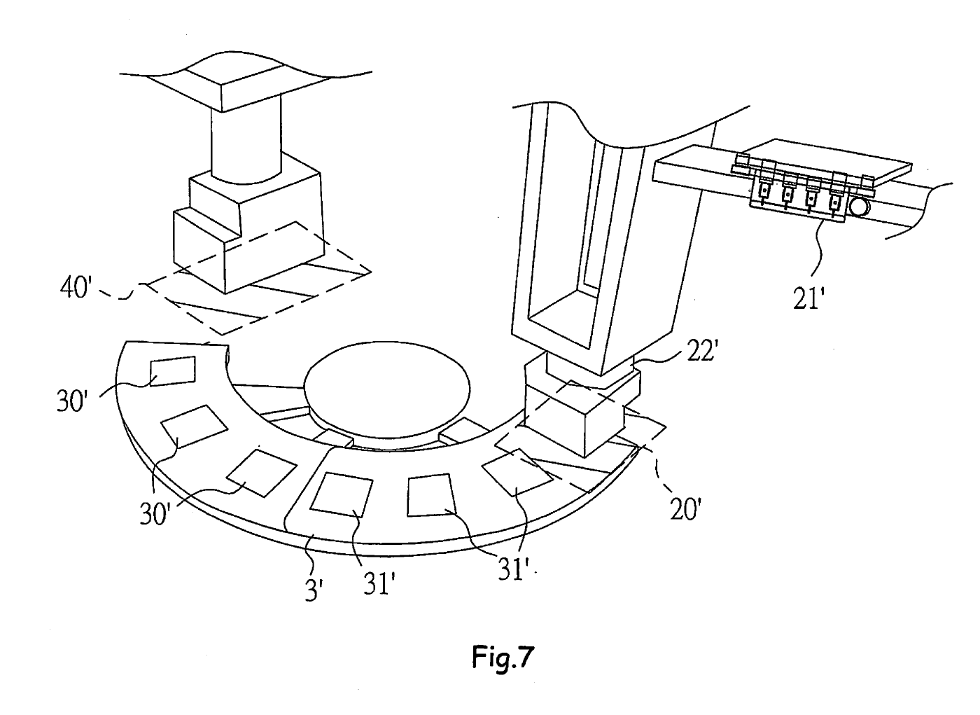

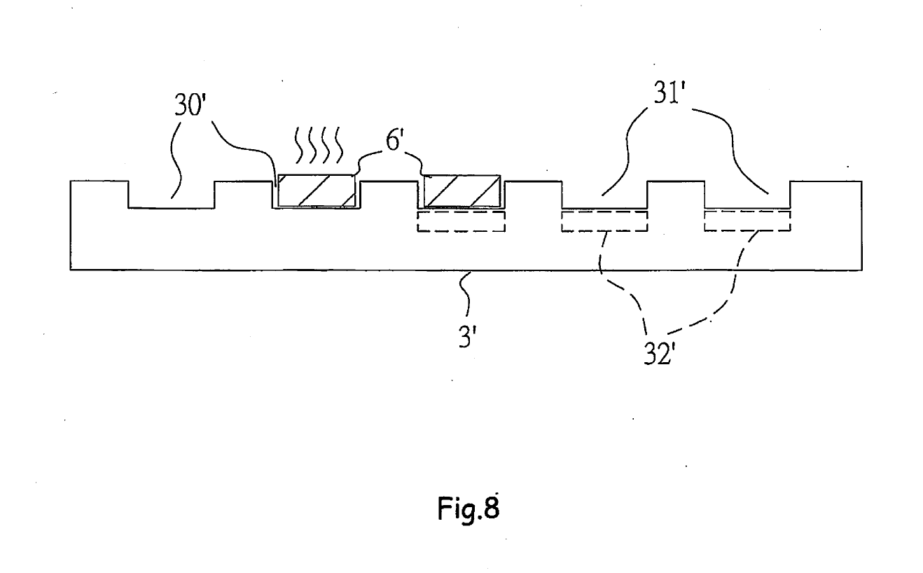

Certainly, it is understood readily by those skilled in the art that the present invention is not limited to the case that all of the buffers on the sector conveyance device are thermally controllable. Because the object which has been tested is intended originally to return the ambient temperature state from the operating temperature, in the second preferred example of the application as shown in FIGS. 7 and 8, on the sector conveyance device 3′, besides the plurality of soaking buffers arranged thereon as illustrated in the previous example, for example, two standing buffers 30′ without active thermally conditioning mechanism are provided additionally. As one IC 6′ has been tested, the sector conveyance device 3′ will pivot the empty standing buffer 30′ to the test location 40′ and carry the IC 6′ so that the temperature of the IC 6′ returns naturally. This is different from the first embodiment, in which the temperature is conditioned to ambient temperature by a set of heat exchanger modules 32′.

Furthermore, after the IC 6′ which has been tested is placed in the standing buffer 30′ for a predetermined time period and the temperature of IC 6′ returns naturally, the sector conveyance device 3′ will pivot to the transferring location 20′, the IC 6′ which has been tested in the standing buffer 30′ is picked up and taken out by the transferring arm 22′, and the IC 6′ which has been tested is transferred out of the test apparatus by the shuttle 21′ of the transferring device. Then, the shuttle 21′ puts a new IC 6′ to be tested in a soaking buffer 31′ for thermal condition.

The preferred embodiments are shown and described herein; however, the present invention is not limited to the preferred embodiments contained in this description. It should be understood that various changes and modifications may be made without departing from the spirit or scope of the appended claims.

### LIST OF REFERENCE NUMERALS

2 transferring device

20, 20′ transferring location

21′ shuttle

22, 22′ transferring arm

3, 3′ sector conveyance device

30′ standing buffer

32, 32′ heat exchanger module

31, 31′ soaking buffers

4 test device

40, 40′ test location

41 test base

42 robot arm

5 pivot

6, 6′ IC

90 thermal insulation chamber of prior art

91 test device of prior art

92 thermally conditioning device of prior art

What is claimed is:

1. A test apparatus, including:
a sector conveyance device pivotably mounted by a pivot and formed with a plurality of soaking buffers, said soaking buffers being used to carry a plurality of electronic components, the sector conveyance device being pivoted to a test location or a transferring location by the pivot;
a transferring device arranged in correspondence to the transferring location for transferring each of the electronic components into or out of the sector conveyance device; and
a test device arranged in correspondence to the test location for testing one electronic component, which is picked up at the test location from the sector conveyance device, of the electronic components, after the one electronic component is tested, the tested one electronic component being placed in the sector conveyance device;
wherein, after the one electronic component is tested, during a period in which the test device tests a next electronic component to be tested, the sector conveyance device is pivoted away from the test location to the transferring location so that the tested one electronic component is transferred out of the sector conveyance device by the transferring device and a new electronic component is transferred into the sector conveyance device by the transferring device.

2. The test apparatus according to claim 1, wherein the sector conveyance device includes a heat exchanger module which is capable of thermally conditioning the soaking buffers.

3. The test apparatus according to claim 1, wherein the transferring device includes a shuttle conveying the electronic components, and a transferring arm transferring the electronic components from the shuttle to the sector conveyance device or from the sector conveyance device to the shuttle.

4. The test apparatus according to claim 1, wherein the test device includes at least one test base and at least one robot arm, the at least one test base and the at least one robot arm being located at the test location, the at least one robot arm being provided to transfer the one electronic component from the sector conveyance device to the test base and allow the one electronic component to be tightly fitted with the test base or to separate the one electronic component from the test base and transfer the one electronic component from the test base to the sector conveyance device.

5. The test apparatus according to claim 1, wherein the sector conveyance device further includes at least one standing buffer provided to receive the tested one electronic component; and in the case that the tested one electronic component is received in the at least one standing buffer, the at least standing buffer is moved to the transferring location through pivoting the sector conveyance device by the pivot.

6. The test apparatus according to claim 5, wherein after the at least one new electronic component to be tested is transferred to the sector conveyance device, the sector conveyance device is pivoted away from the transferring location so that the standing buffer is located at the test location for receiving the tested one electronic component from the test device.
